(19) United States
(12) Patent Application Publication
(10) Pub. No.: US 2004/0217431 A1
(43) Pub. Date: Nov. 4, 2004

(54) Semiconductor device and method for manufacturing the same

(76) Inventor: Hiroyuki Shimada, Kofu-shi (JP)

Correspondence Address: EDWARDS & ANGELL, LLP, P.O. BOX 55874, BOSTON, MA, 02205, US

(21) Appl. No.: 10/810,246

(22) Filed: Mar. 26, 2004

(30) Foreign Application Priority Data
Mar. 28, 2003 (JP) 2003-091332
Jul. 22, 2003 (JP) 2003-277404

(51) Int. Cl. H01L 29/76

(52) U.S. Cl. 257/411

(57) ABSTRACT

A semiconductor device having a gate insulator layer in which the contamination with oxygen atoms is controlled and a method for manufacturing the same is provided. The semiconductor device comprises: a semiconductor layer; a gate insulator layer formed on the semiconductor layer; and a gate electrode formed on the gate insulator layer, wherein the atomic ratio of oxygen atoms included in the gate insulator layer is 5 atm. % or below.

Japanese Patent Application 2003-091332 filed on Mar. 28, 2003 and Japanese Patent Application 2003-277404 filed on Jul. 22, 2003 are hereby incorporated by reference in their entirety.

### BACKGROUND

1. Field of the Invention

The present invention relates to a semiconductor device and a method for manufacturing the same, and more particularly, to a semiconductor device with special characteristics in the gate insulator layer and a method for manufacturing the same.

2. Description of the Related Art

Micro MIS-type transistors (MISFET), wherein the thickness of the gate insulator layer has been reduced to an extremely small value, can be expected to feature a very high drivability due to a lot of carriers being induced in the channel-forming region. There is however the problem, that alongside with reducing the thickness of the gate insulator layer, an increasingly enormous direct tunneling current flows between the gate electrode and the semiconductor layer, leading to an extraordinary increase in the power consumption of the semiconductor device. Therefore, it has often been tried to reduce the direct tunneling current by adopting a material with a larger relative dielectric constant than that of the silicon dioxide layer commonly used as a gate insulator layer so as to increase the physical thickness of the film.

It is being studied to use metal oxides having a greater dielectric constant than silicon oxide. For such metal oxides, the usage of oxides of aluminum, hafnium, tantalum and lanthanum as a gate insulator layer have been reported. However, when using these metal oxides as a gate insulator layer, problems occurred in that as a consequence of the detachment of oxygen atoms, an interface reaction layer with a low relative dielectric constant developed at the interface between the gate insulator layer and the semiconductor, or, at the interface between the gate insulator layer and the gate electrode.

Further, it has been considered to use a silicon nitride layer by itself or a combination of a silicon nitride layer with another insulator layer as a gate insulator layer, silicon nitride having a larger relative dielectric constant than silicon oxide as disclosed in Japanese Patent Publication Laid-open Nos. 2002-76336 and 2000-252462. However, in conventional depositing methods such as CVD for forming the silicon nitride layer, the contamination with oxygen atoms cannot be sufficiently controlled, and there is thus the problem of a decrease in the relative dielectric constant of the gate insulator layer. Furthermore, in the conventional manufacturing methods, it is not easy to prevent the contamination of oxygen atoms into the gate insulator layer composed of the silicon nitride layer.

### SUMMARY

The present invention is intended to provide a semiconductor device with a high relative dielectric constant wherein the contamination with oxygen atoms is suppressed and a method for manufacturing the same.

A semiconductor device according to one aspect of the present invention includes a semiconductor layer, a gate insulator layer formed on the semiconductor layer, and a gate electrode formed on the gate insulator layer. The atomic ratio of oxygen atoms included in the gate insulator layer is 5 atm. % or below.

In the semiconductor device according to the present invention, the atomic ratio of oxygen atoms included in the gate insulator layer is controlled to be 5 atm. % or less. As a result, a semiconductor device can be provided having a gate insulator layer with few impurities and a high relative dielectric constant.

The semiconductor device according to another aspect of the present invention includes a semiconductor layer, a gate insulator layer formed on the semiconductor layer and having an interface reaction layer, and a gate electrode formed on the gate insulator layer. The atomic ratio of oxygen atoms included in the gate insulator layer is 5 atm. % or below.

In a semiconductor device according to other aspect of the present invention, the gate insulator layer has interface reaction layers that develop at the interfaces between this gate insulator layer and the semiconductor layer and the gate electrode, respectively, and the atomic ratio of oxygen atoms included in the gate insulator layer including the interface reaction layer is controlled to be 5 atm. % or less. As a result, a semiconductor device can be provided having a gate insulator layer with few impurities and a high relative dielectric constant.

A method for manufacturing a semiconductor device according to another aspect of the present invention includes, in the following order, a) preparing a substrate having a semiconductor layer, b) transferring the substrate to a first process chamber, and c) providing material to become a gate insulator layer on the semiconductor layer in the first process chamber. The method also includes d) transferring the substrate from the first process chamber to a second process chamber via a transfer path, and e) providing material to become a gate electrode on the gate insulator layer in the second process chamber. In the first process chamber of the step c), the transfer path of the step d) and the second process chamber of the step e), the partial pressure of oxygen in the environment is kept at 10 ppm or below.

The expression “partial pressure of oxygen” stated here is to be understood as not only the partial pressure of oxygen itself but rather to also include the partial pressure of oxygen compounds such as water and the like.

In the method for manufacturing a semiconductor device according to another aspect of the present invention, the contamination of the gate insulator layer with oxygen atoms is controlled, and thus a drop of the relative dielectric constant of the gate insulator layer can be prevented.

### BRIEF DESCRIPTION OF THE DRAWINGS

FIG. 1 is a sectional view showing a semiconductor device manufactured by a method for manufacturing according to the present embodiment.

FIG. 2 is a sectional view showing the method for manufacturing a semiconductor device according to the present embodiment.

FIG. 3 is a sectional view showing the method for manufacturing a semiconductor device according to the present embodiment.

FIG. 4 is a sectional view showing the method for manufacturing a semiconductor device according to the present embodiment.

FIG. 5 is a drawing showing system units used in the method for manufacturing a semiconductor device according to the present embodiment.

FIG. 6 is a diagram showing a result of a composition analysis of a silicon nitride layer in the case of being exposed to the air.

### DESCRIPTION OF THE PREFERRED EMBODIMENTS

Following is an explanation of embodiments of the present invention with reference to the drawings.

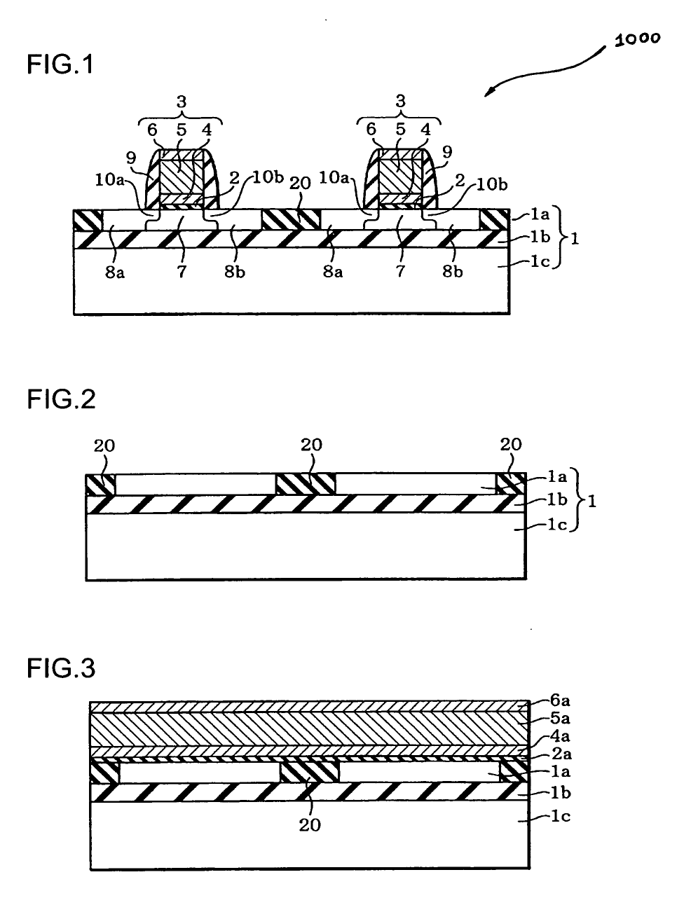

FIG. 1 is a sectional view schematically showing a semiconductor device 1000 according to an embodiment of the present invention.

The semiconductor device 1000 is a complementary semiconductor device, and comprises an n-channel gate-insulated field effect transistor (NMISFET) 100A and a p-channel gate-insulated field effect transistor (PMISFET) 100B. The NMISFET 100A and PMISFET 100B are formed on an SOI (Silicon On Insulator) substrate 1. The SOI substrate 1 has a multi-layer structure, that is, on a supporting substrate 1c there is an insulator layer 1b (silicon oxide layer) and a semiconductor layer 1a. In the present embodiment, the semiconductor layer 1a is a silicon layer. The semiconductor layer can also be a bulk semiconductor substrate. Furthermore, the NMISFET 100A and PMISFET 100B are isolated from each other by an isolation regions 20 formed onto the semiconductor layer 1a of the SOI substrate 1.

Each MISFET 100A and 100B has a structure wherein a multi-layer gate electrode 3 is formed on the semiconductor layer 1a through a gate insulator layer 2.

In the present embodiment, the atomic ratio of oxygen atoms included in the gate insulator layer 2 is 5 atm. % or below and preferably 3 atm. % (or below). The gate insulator layer 2 preferably is a silicon nitride (Si₃N₄) layer. It is furthermore desirable that the gate insulator layer 2 does not have an interface reaction layer including oxygen at the interface with the semiconductor layer 1a or the interface with the gate electrode 3.

If, however, the gate insulator layer 2 has an interface reaction layer including oxygen at the interface with the semiconductor layer 1a or the interface with the gate electrode 3, it is desirable for the thickness of this interface reaction layer to be thinner.

That is to say, it is desirable that the atomic ratio of oxygen atoms in the gate insulator layer 2 including the interface reaction layer is 5 atm. % or below, and preferably 3 atm. % or below. In this way, the occurrence of oxides that have a low relative dielectric constant can be suppressed by limiting the atomic ratio of oxygen atoms included in the gate insulator layer 2.

As a result, the relative dielectric constant of the gate insulator layer 2 can be increased in value, for example, a relative dielectric constant value of 7 or higher can be achieved.

The gate electrode 3 has a multi-layer structure, having in this order a tantalum nitride layer (bottom tantalum nitride layer) 4, a body centered cubic lattice tantalum layer 5, and as a cap layer a tantalum nitride layer (top tantalum nitride layer) 6. Further, directly underneath the gate insulator layer 2 a channel-forming region 7, and to both sides of the channel-forming region 7 source and drain regions 8a and 8b have been designed. Furthermore, in the NMISFET 100A, the source/drain regions 8a, 8b are formed as n-type, in the PMISFET 100B the source/drain regions 8a, 8b are formed as p-type. Between the source/drain regions 8a, 8b and the channel-forming region 7, extension regions 10a, 10b are formed. At the upper part of the source/drain regions 8a, 8b, silicide layers not shown in the drawing can be respectively formed.

The semiconductor device 1000 of the present embodiment can be manufactured by following the below-mentioned steps. In the present embodiment, a multi chamber system or a cluster system or the like can be preferably used. FIG. 5 shows an example of a cluster system unit. This unit has a load lock chamber 40, a first process chamber 50, a second process chamber 60, a transfer chamber 70 and the like. The load lock chamber 40, the first process chamber 50 and the second process chamber 60 are placed around the transfer chamber 70 in order to enable successive processing of each processing step. Specifically, the object to be processed (SOI substrate 1) accommodated in the load lock chamber (cassette chamber) 40 is transferred via the transfer chamber (cluster center chamber) 70 to the first process chamber (plasma chamber) 50, where the gate insulator layer 2 is formed. Next, the SOI substrate 1 is transferred from the first process chamber 70 via the transfer chamber 70 to the second process chamber (sputter chamber) 60, where the gate electrode 3 is formed. And in each chamber, the partial pressure of oxygen is controlled. Below, each process step is explained.

(a) As shown in FIG. 2, the SOI substrate 1 is prepared, wherein the SOI substrate includes the semiconductor layer (e.g. a low concentration p-type silicon layer) 1a and the insulator layer (e.g. a silicon oxide layer) 1b deposited on the supporting substrate 1c. The SOI substrate 1 is accommodated in the load lock chamber 40 shown in FIG. 5. In this step, the partial pressure of oxygen is at least kept at 10 ppm or less, and preferably at 1 ppm or less.

The thickness of the semiconductor layer 1a of the SOI substrate 1 is, for example, 30 nm. The semiconductor layer 1a of the SOI substrate 1 is divided into element forming regions for MIS type transistors or the like that are each isolated from each other. The isolating in the semiconductor layer 1a is carried out with trenches formed into the semiconductor layer 1a by dry-etching method or isolation regions formed through STI (Shallow Trench Isolation) method and the like.

(b) Next, as shown in FIG. 5, the SOI substrate 1 is transferred via the transfer chamber (cluster center chamber) 70 to the first process chamber (plasma chamber) 50.

In the first process chamber 50, a silicon nitride layer 2a to become the gate insulator layer is formed on the semiconductor layer 1a by introducing a gas comprising nitrogen or a nitrogen compound into the chamber and letting the nitrogen species activated by plasma excitation directly react with the silicon of the semiconductor layer 1a, that is to say, by direct plasma reaction. In this film-building step, the partial pressure of oxygen is at least kept at 10 ppm or less, and preferably at 1 ppm or less.

As a nitrogen species constituting gas, nitrogen, ammonia and the like can be used. If nitrogen is used as a nitrogen species, it can be used in combination with hydrogen and rare gases like argon, xenon and others. In this case, for example, the compositional ratio (N/H/rare gas) of nitrogen, hydrogen and rare gas can be more or less around 7/3/90.

If ammonia is used as a nitrogen species, it can be used in combination with rare gases like argon, krypton, xenon and others. In this case, it is desirable to set the flow rate (ammonia/rare gas) of ammonia and rare gas to be, for example., 2/98 to 20/80. If the amount of ammonia is higher than the above-mentioned upper limit, the hydrogen entering the silicon nitride layer increases, and there is a tendency for the reliability to decrease with the increase of the rate of hydrogen not contributing to dangling bond terminations. On the other hand, if the amount of ammonia is lower than the above-mentioned lower limit, the source of nitrogen becomes too small, the film properties drop, for example, hysteresis occurs in the capacitance properties (C—V properties). The film thickness of the silicon nitride layer is 1 to 7 nm, varying with the film forming conditions.

The first process chamber 50 is a high-density plasma unit, and preferably a microwave enhanced high-density plasma unit utilizing an RLSA (Radial Line Slot Antenna). As the plasma used in this unit is of an extraordinarily low electron temperature (1 eV or less), the plasma nitrification with this unit has the merit of enabling the formation of a nitride film at low temperatures causing extraordinarily little damage. Furthermore, to reduce the plasma damage, a high-density plasma method of 2.54 GHz allowing low electron temperatures can be used to provide the material to become the gate insulator layer.

The silicon nitride layer formed in this step has few impurities, a good uniformity and a high relative dielectric constant.

(c) Next, as shown in FIG. 5, the SOI substrate 1 onto which the silicon nitride layer 2a has been formed is transferred from the first process chamber 50 via the transfer chamber 70 to the second process chamber (sputter chamber) 60. In the second process chamber 60, the partial pressure of oxygen is at least kept at 10 ppm or less, and preferably at 1 ppm or less.

In the second process chamber 60, as shown in FIG. 3, according to the sputtering method using xenon gas, a bottom tantalum nitride layer 4a, a body centered cubic lattice tantalum layer 5a, and a top tantalum nitride layer 6a are deposited successively one after the other on the silicon nitride layer 2a. In these film-forming steps, the contamination with impurities can be decreased by adopting the sputtering method. Further, by choosing xenon gas instead of argon gas as a rare gas to be used in the sputtering process of the material to become the gate electrode, a low interfacial density of states can be achieved, and the occurrence of defects and damages in the silicon nitride layer 2a can be reduced.

When considering the aspect of the conductivity properties and the threshold value properties, it is desirable for the nitrogen and the tantalum in the bottom tantalum nitride layer 4a expressed as TaNs to have a composition ratio (x) of 0.25 to 1.0.

To give an example for the film thickness of the layers constituting the gate electrode 3, the bottom tantalum nitride layer 4a has a film thickness of 30 nm, the body centered cubic lattice tantalum layer 5a a film thickness of 100 nm, and the top tantalum nitride layer 6a a film thickness of 30 nm. The gate electrode of tantalum nitride and tantalum is advantageous compared to conventional gate electrodes of poly-crystalline silicon in terms of not leading to gate depletion. It is further an advantage point, that the bottom tantalum nitride layer 4a is unlikely to develop an interface reaction layer including oxygen at its interface with the gate insulator layer 2.

It is furthermore preferable to form these layers, the bottom tantalum nitride layer 4a, the body centered cubic lattice tantalum layer 5a, and the top tantalum nitride layer 6a, consecutively and thereby preventing contact with the air. If the films are exposed to the air while forming the films, water particles will adhere and the forming of oxides at the film surface will occur, which is not favorable.

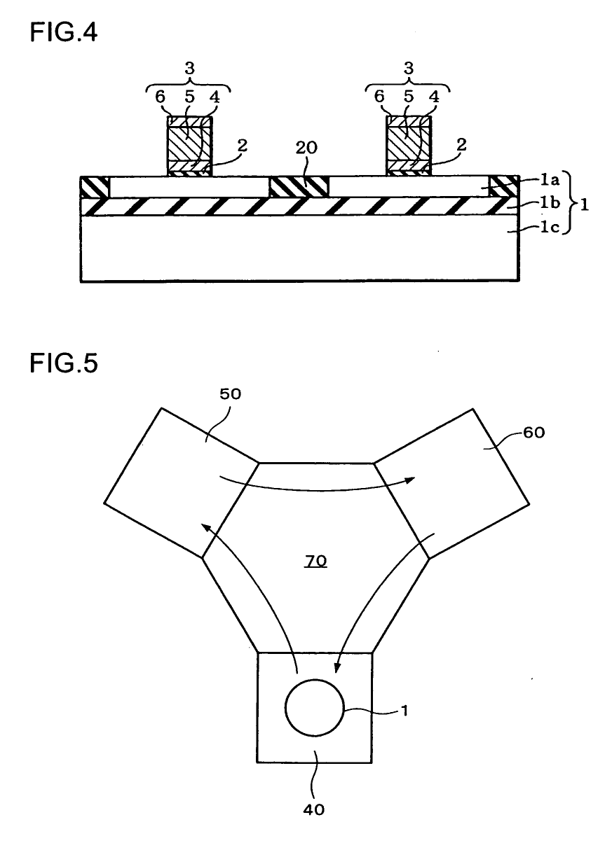

(d) Next, the SOI substrate 1 will be pattern-processed either in the second process chamber 60 shown in FIG. 5, or in another process chamber not shown in the drawing. That is to say, as shown in FIG. 4, the gate electrode 3 is formed by patterning the multi-layer body consisting of the bottom tantalum nitride layer 4a, the body centered cubic lattice tantalum layer 5a, and the top tantalum nitride layer 6a, by lithography technology and by dry etching technology. That is to say, the gate electrode 3 has a multi-layer structure, consisting of the bottom tantalum nitride layer 4, the body centered cubic lattice tantalum layer 5, and the top tantalum nitride layer 6. In this example, the gate insulator layer 2 is formed by patterning the silicon nitride layer 2a right afterward. For the patterning of the above-mentioned multi-layer body, it is desirable to use highly selective dry etching using a gas mixture of NF₃ and SiC₄. Through this etching, the multi-layer body is processed into the gate electrode 3 of 65 nm gate length.

The gate electrode 3 formed by the above-mentioned method has a low resistance, its sheet resistance being about 2 ohms/sq.

(e) Next, as shown in FIG. 1, impurities are implanted into the semiconductor layer la using the gate electrode 3 as a mask, thereby forming the extension regions 10a, 10b of the source/drain regions inside this semiconductor layer 1a. After that, a sidewall insulator layer 9 is formed at the sidewalls of the gate electrode 3. The sidewall insulator layer 9 is formed by anisotropic etching of the silicon nitride layer that has been formed by using high-density CVD at a low temperature of 500 degrees centigrade or below. The width of the sidewall insulator layer 9 is for example 50 nm. Next, using the gate electrode 3 and the sidewall insulator layer 9 as a mask, impurities are implanted into the semiconductor layer 1a, thereby forming the source/drain regions 8a, 8b inside this semiconductor layer 1a. After that, an interlayer insulator layer (not shown in the drawing) of a thickness of 800 nm is formed by low temperature CVD method (LTO). After that, each impurity is activated by solid phase epitaxy method (SPE) at 550 degrees centigrade or below.

The further steps use the same methods as conventional CMOS type transistor forming methods to complete the semiconductor device 1000.

This semiconductor device and the method for manufacturing the same feature the following characteristics.

In this embodiment, the first process chamber (plasma chamber) 50 for providing the material to become the gate insulator layer 2 and the second process chamber (sputter chamber) 60 for providing the material to become the gate electrode 3 are coupled to each other via the transfer chamber (center cluster chamber) 70.

The important point is that at least in the first process chamber and the second process chamber and the transfer path coupling both process chambers an environment with a partial pressure of oxygen atoms of 10 ppm or below is preserved.

That is to say, the object to be processed is not exposed to an environment where the partial pressure of oxygen atoms exceeds 10 ppm while processing the step of providing material to become the gate insulator layer, the step of providing material to become the gate electrode and the step of transferring the object to be processed between these two steps. By observing this, the contamination of the gate insulator layer with oxygen atoms can be controlled.

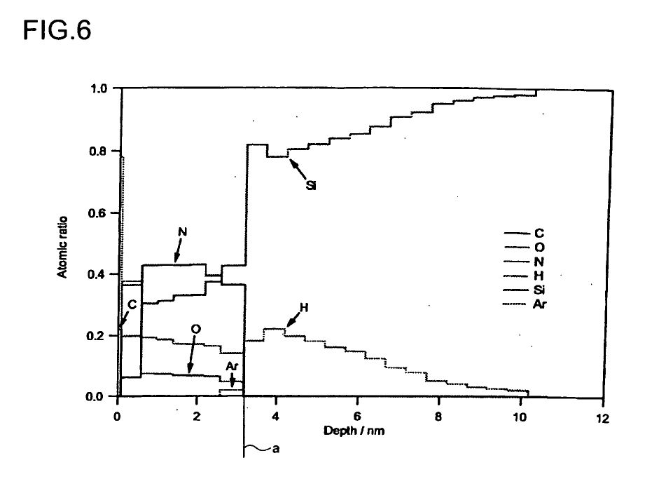

If the contamination with oxygen atoms in the gate insulator layer were to be left uncontrolled, or in other words, if the gate insulator layer happened to be exposed to the general atmosphere (air) after being formed, due to the adsorption of water particles and the like, the gate insulator layer would be contaminated with a large amount of oxygen atoms throughout the gate insulator layer, and the equivalent relative dielectric constant value would drop to 6.8 or less. This is clearly understood from the result of the composition analysis by RBS (Rutherford backscattering spectrometry) shown in FIG. 6. FIG. 6 shows the film composition of a sample in which a silicon nitride layer of about 3 nm was formed onto a silicon substrate. The conditions of forming the silicon nitride layer were the same as in the embodiment except for that the substrate was exposed to the air. In FIG. 6, the horizontal axis shows the depth from the surface of the silicon nitride layer, while the vertical axis shows the rate of each atom. The line shown in FIG. 6 marked by “a” corresponds to the surface of the silicon layer. FIG. 6 shows that oxygen is included in the silicon nitride layer at a ratio of around 7 atm. %. From this it becomes clear that before and after forming the gate insulator layer (silicon nitride layer) if the substrate is exposed to the air the silicon nitride layer gets contaminated with oxygen and the relative dielectric constant becomes much smaller than that of silicon nitride.

On the other hand, by controlling the partial pressure of oxygen as mentioned before in the specific steps according to this embodiment, the intrusion of oxygen into the gate insulator layer can be suppressed. The atomic ratio of oxygen atoms in the gate insulator layer (silicon nitride layer) formed according to the corresponding method is controlled to 5 atm. % or below. When determining the atomic ratio of oxygen in the gate insulator layer, the following three situations are taken into account: (1) an interfacial reaction layer is formed between the silicon nitride layer and the silicon layer; (2) an interfacial reaction layer is formed between the silicon nitride layer and the bottom tantalum nitride layer; and (3) both (1) and (2) are formed. It is preferable for the atomic ratio of oxygen of the gate insulator layer (silicon nitride layer) including the interfacial reaction layer to be controlled to 5 atm. % or below or even more preferably to 3 atm. % or below.

In this way, with this embodiment, an equivalent relative dielectric constant of the gate insulator layer of 7 or more can be maintained, and thus a stable MNS type semiconductor device with high drivability can be provided.

Above, an embodiment of the present invention has been described, but the present invention is not limited to the above-mentioned embodiment but applied to various kinds of modifications within the scope of the claims of the present invention. For example, according to the above-mentioned embodiment the semiconductor layer is an SOI, but the semiconductor layer is not limited to this, and can also be a bulk semiconductor substrate. It is further possible in this invention to apply a salicide structure or a damascene gate structure.

What is claimed is:

1. A semiconductor device, comprising:
a semiconductor layer;
a gate insulator layer formed on the semiconductor layer; and
a gate electrode formed on the gate insulator layer, wherein the atomic ratio of oxygen atoms included in the gate insulator layer is 5 atm. % or below.

2. A semiconductor device, comprising:
a semiconductor layer;
a gate insulator layer formed on the semiconductor layer and having an interface reaction layer; and
a gate electrode formed on the gate insulator layer, wherein the atomic ratio of oxygen atoms included in the gate insulator layer is approximately 5 atm. % or below.

3. The semiconductor device according to claim 1 or 2, wherein the gate insulator layer is a silicon nitride layer.

4. The semiconductor device according to claim 3, wherein the silicon nitride layer is formed by the reaction of a nitrogen species activated by plasma excitation directly with the semiconductor layer.

5. The semiconductor device according to any one of claims 1, 2, or 4, wherein the gate electrode includes a tantalum nitride layer.

6. The semiconductor device according to claim 5, wherein the tantalum nitride layer is formed by sputtering.

7. A method for manufacturing a semiconductor device, comprising, in the following order:
a) preparing a substrate having a semiconductor layer;
b) transferring the substrate to a first process chamber;
c) providing material to become a gate insulator layer on the semiconductor layer in the first process chamber;
d) transferring the substrate from the first process chamber to a second process chamber via a transfer path; and
e) providing material to become a gate electrode on the gate insulator layer in the second process chamber, wherein in the first process chamber of step c), the transfer path of step d) and the second process chamber of step e), the partial pressure of oxygen is kept at approximately 10 ppm or below.

8. The method for manufacturing a semiconductor device according to claim 7, wherein the atomic ratio of oxygen atoms included in the gate insulator layer is 5 atm. % or below.

9. The method for manufacturing a semiconductor device according to claim 7 or 8, wherein the gate insulator layer is a silicon nitride layer.

10. The method for manufacturing a semiconductor device according to claim 9, wherein the silicon nitride layer is formed by letting a nitrogen species activated by plasma excitation directly react with the semiconductor layer.

11. The method for manufacturing a semiconductor device according to claim 10, wherein the silicon nitride layer is formed by letting a nitrogen species in a state of high-density plasma with a low electron temperature of 1 eV or less directly react with the semiconductor layer.

12. The method for manufacturing a semiconductor device according to any one of claims 7, 8, 10, or 11, wherein the gate electrode includes a tantalum nitride layer formed by sputtering.

13. The method for manufacturing a semiconductor device according to claim 7, wherein said gate electrode is formed using a sputtering method using Xenon gas.

14. The method of claim 13, wherein said gate electrode comprises a bottom tantalum nitride layer of TaNx, wherein x is in the range of approximately 0.25 to approximately 1.0.

15. The method of claim 14, wherein said gate electrode further comprises a tantalum layer and a silicon nitride layer.

16. The method of claim 15, wherein said bottom tantalum nitride layer, said tantalum layer and silicon nitride layer are formed consecutively.

17. The method of claim 7, wherein in step (c), said material comprises nitrogen, ammonia, and a rare gas having a compositional ratio of approximately 7/3/90.

18. The method of claim 17, wherein a ratio of flow rates of ammonia and rare gas is in the range of approximately 2/98 to approximately 20/80.

19. A method for manufacturing a semiconductor device, comprising:
a) preparing a substrate having a semiconductor layer;
b) transferring the substrate to a first process chamber;
c) providing material to become a gate insulator layer on the semiconductor layer in the first process chamber;
d) transferring the substrate from the first process chamber to a second process chamber via a transfer path; and
e) providing material to become a gate electrode on the gate insulator layer in the second process chamber, wherein in the first process chamber of step c), the transfer path of step d) and the second process chamber of step e), the partial pressure of oxygen is kept at approximately 10 ppm or below.
